(19) United States
(12) Patent Application Publication
(10) Pub. No.: US 2026/0140205 A1
(43) Pub. Date: May 21, 2026

(54) PROCESS FOR MANUFACTURING A WHEATSTONE BRIDGE

(71) Applicant: COMMISSARIAT À L'ENERGIE ATOMIQUE ET AUX ENERGIES ALTERNATIVES, PARIS (FR)

(72) Inventors: Sophie GIROUD, GRENOBLE (FR); Bertrand DELAET, Grenoble (FR)

(21) Appl. No.: 19/387,443

(22) Filed: Nov. 12, 2025

(30) Foreign Application Priority Data
Nov. 21, 2024 (FR) 2412795

(51) Int. Cl. G01R 33/02; B32B 7/025; B32B 7/03; G01R 33/09; H05K 1/18

(52) U.S. Cl. CPC G01R 33/0206; B32B 7/025; B32B 7/03; G01R 33/09; H05K 1/181; B32B 2307/208; B32B 2457/00; H05K 2201/10022

(57) ABSTRACT

A process for manufacturing a Wheatstone bridge, includes the following steps: a step of providing a first wafer including: a first stack of layers including: a first magnetic layer, the first stack of layers being structured into a first Wheatstone device wherein the magnetization of the first magnetic layer is oriented in a first direction, a step of providing a second wafer includes: a second stack of layers including: a third magnetic layer, a first step of structuring the second stack of layers into a second Wheatstone device wherein the magnetization of the third magnetic layer is oriented in a second direction, a bonding step, wherein the bonding step is carried out in such a way that the first direction is different from the second direction.

### CROSS-REFERENCE TO RELATED APPLICATION

This application claims priority to foreign French patent application No. FR 2412795, filed on Nov. 21, 2024, the disclosure of which is incorporated by reference in its entirety.

### FIELD OF THE INVENTION

The invention relates to the field of magnetic-field sensors. More particularly, it relates to a process for manufacturing a Wheatstone bridge.

### BACKGROUND

Magnetoresistance is the property that certain materials or devices have of exhibiting a variation in their electrical resistance in the presence of a magnetic field or a change in their magnetic configuration. Giant magnetoresistance (GMR) is a quantum effect observed in thin-film structures composed of alternating ferromagnetic layers and non-magnetic layers. Within spin valves, two ferromagnetic layers are separated by a non-magnetic layer. By depositing the thin ferromagnetic layers so that their coercivities (magnetic field required to reverse their magnetization) are different, it is possible to switch them separately. The ferromagnetic layer having the highest coercivity is called the “reference layer” or “fixed layer” while the one having the lowest coercivity is called the “free layer”. In such a structure, it is possible to change the magnetization direction of the free layer without changing the magnetization direction of the reference layer. It is therefore possible, simply by manipulating the magnetization of the free layer, to switch from a “parallel” configuration—in which the magnetization of the reference layer and the magnetization of the free layer are oriented substantially in the same direction—to an “antiparallel” configuration—in which the magnetization of the reference layer and the magnetization of the free layer are oriented substantially at 180 degrees to each other.

A resistance difference of several tens of percent may be observed between the parallel configuration and the antiparallel configuration.

An equivalent effect, called tunnel magnetoresistance (TMR), is observed in structures comprising two ferromagnetic layers separated by an insulating non-magnetic layer. In such a structure, called a magnetic tunnel junction (MTJ), current flows through the insulating layer via a tunneling effect. In a magnetic tunnel junction, the TMR differential may reach several hundred percent.

The TMR (or GMR) differential is defined by the following formula:

TMR=R_{AP}−R_{P}/R_{P} with R_{AP} the electrical resistance of the junction in the antiparallel configuration and R_{P} the electrical resistance of the junction in the parallel configuration.

GMR and TMR effects are advantageously employed in measuring devices, to sense and measure magnetic-field variations (Freitas et al. 2007), (Wu, Yihong 2003).

Magnetoresistive magnetic-field sensors are generally designed as Wheatstone bridges in order to compensate for temperature drifts. The balanced Wheatstone bridge must be made up of 4 magnetic resistors (R₁, R₂, R₃, R₄) of identical resistances. For a device employing the TMR effect, each resistor comprises at least one magnetic tunnel junction. As an additional condition, two of the four resistors must have an electrical response to magnetic excitation (ΔR/ΔH) opposite that of the other two magnetic resistors.

Magnetoresistive magnetic-field sensors must therefore comprise two Wheatstone half-bridges comprising magnetic tunnel junctions the magnetizations of the reference layers of which are oriented substantially at 180 degrees to one another, pairwise. Each Wheatstone half-bridge comprises two Wheatstone quarter-bridges, each Wheatstone quarter-bridge comprising one magnetic resistor.

In the prior art, there are a number of solutions allowing such devices to be manufactured.

In the document U.S. Pat. No. 9,234,948B2, the two Wheatstone half-bridges are assembled individually at the packaging level. Such a solution results in expensive packaging and is prone to mechanical alignment errors.

In the document (Freitas et al. 2016) two identical deposits are deposited in two separate regions of the wafer, the deposits comprising an antiferromagnetic material which does not require magnetic annealing. Such a solution is expensive and has a poor resistance to magnetic shocks and high temperatures. In addition, such a solution is incompatible with magnetic tunnel junctions, the magnetic tunnel junction needing to be subject to a high-temperature anneal for the TMR effect to appear.

In the document (Luong et al. 2015), a flux-guide is used. Such a solution is expensive and difficult to implement.

It is also known in the prior art to use an antiferromagnetic layer and/or a synthetic antiferromagnet (SAF) coupled to the reference layer to fix the magnetization direction of the latter. A synthetic antiferromagnet is an artificial antiferromagnet comprising two ferromagnetic layers separated by a non-magnetic layer. In a synthetic antiferromagnet, the two magnetic layers are coupled magnetically and in parallel but opposite directions, this having the effect of cancelling their magnetizations. By locally heating the antiferromagnetic layer to a temperature above its blocking temperature, while applying a magnetic field, it is possible to selectively reorient the magnetization of the reference layers. Such a solution is expensive and difficult to implement, this making it unsuitable for large-scale production. In addition, the selective anneal is observed to decrease the performance of the obtained device.

There is therefore a need to produce, simply, inexpensively and in a manner suitable for large-scale production, a Wheatstone bridge comprising magnetic resistors the magnetizations of the reference layers of half of which are aligned in a first direction and the magnetizations of the reference layers of the other half of which are aligned in a second direction oriented substantially at 180 degrees from the first direction.

### SUMMARY OF THE INVENTION

One subject of the invention is a process for manufacturing a Wheatstone bridge, comprising:
a step of providing a first wafer comprising:
   a first substrate,
   a first stack of layers stacked in a first stacking direction and placed on the first substrate, comprising:
      a first magnetic layer,
      a second magnetic layer,
   the first stack of layers being structured into a first Wheatstone device comprising a first resistor and a second resistor, each of said resistors comprising at least two magnetoresistive devices in which the magnetization of the first magnetic layer is oriented in a first direction,
a step of providing a second wafer comprising:
   a second substrate,
   a second stack of layers stacked in a second stacking direction and placed on the second substrate, comprising:
      a third magnetic layer,
      a fourth magnetic layer,
a first step of structuring the second stack of layers into a second Wheatstone device comprising a third resistor and a fourth resistor, each of said resistors comprising at least two magnetoresistive devices in which the magnetization of the third magnetic layer is oriented in a second direction,
a bonding step in which the upper part of the second Wheatstone device is bonded to the upper part of the first Wheatstone device,
   wherein the bonding step is carried out in such a way that the first direction is different from the second direction.

Advantageously, the complete Wheatstone bridge is manufactured via wafer-level assembly, allowing production at lower cost. Advantageously, the obtained Wheatstone bridge is compact because the two Wheatstone devices are stacked vertically.

According to particular embodiments of such a process:
the bonding layer is obtained by chemical treatment of an insulating layer insulating the resistors;
the bonding layer is obtained by depositing a metal, a semiconductor, an oxide or a nitride;
the process further comprises a step of removing the second substrate from the second wafer;
the process further comprises a second structuring step in which the electrical connections of the second Wheatstone device are made;
the process further comprises a connecting step in which the first Wheatstone device and the second Wheatstone device are electrically connected;
the first structuring step is carried out after the bonding step;
the first structuring step is carried out before the bonding step;
the second structuring step is carried out before the bonding step and after the first structuring step;
the second wafer further comprises a demounting layer located between the second substrate and the multilayer and the removing step is carried out by demounting the second substrate by stressing the demounting layer;
the demounting layer comprises platinum;
wherein the first direction is oriented substantially at 180 degrees to the second direction;
the first direction and the second direction are substantially parallel to a plane orthogonal to the first stacking direction of the first multilayer and to the second stacking direction of the second multilayer;
the first direction is substantially orthogonal to the second direction;
the first direction is substantially orthogonal to the plane and the second direction is substantially parallel to the plane;
the magnetization direction of the first magnetic layer is substantially perpendicular to the magnetization direction of the second magnetic layer, and the magnetization direction of the third magnetic layer is substantially perpendicular to the magnetization direction of the fourth magnetic layer.

Another subject of the invention is a Wheatstone bridge comprising:
a first stack of layers structured into a first Wheatstone device comprising a first resistor and a second resistor, each of said resistors comprising at least two magnetoresistive devices, which comprise:
   a first magnetic layer the magnetization of which is oriented in a first direction,
   a second magnetic layer,
a second stack of layers structured into a second Wheatstone device comprising a third resistor and a fourth resistor, each of said resistors comprising at least two magnetoresistive devices, which comprise:
   a third magnetic layer the magnetization of which is oriented in a second direction,
   a second magnetic layer,
      wherein the first direction is different from the second direction,
      wherein the upper part of the first Wheatstone device is bonded to the upper part of the second Wheatstone device via a bonding layer.

Another subject of the invention is a magnetic-field sensor comprising at least three Wheatstone bridges according to any of the embodiments of the invention, wherein three of the at least three Wheatstone bridges are each oriented according to a unit vector, the unit vectors forming a basis of three-dimensional coordinates.

### BRIEF DESCRIPTION OF THE DRAWINGS

Other features, details and advantages of the invention will become apparent on reading the description given with reference to the appended drawings, which are given by way of example, and in which, respectively:

FIG. 1 is a simplified schematic of a Wheatstone bridge according to one embodiment of the invention;

FIG. 2 is a schematic diagram of a Wheatstone bridge according to one embodiment of the invention;

FIG. 3 is a schematic diagram of a Wheatstone bridge in a step of removing the substrate of one of the two Wheatstone devices;

FIG. 4 is a schematic diagram of a Wheatstone bridge in a bonding step of a manufacturing process according to a first embodiment of the invention;

FIG. 5 is a schematic diagram of a Wheatstone bridge in a bonding step of a manufacturing process according to a second embodiment of the invention;

FIG. 6 is a schematic diagram of a Wheatstone bridge in a bonding step of a manufacturing process according to a third embodiment of the invention;

FIG. 7 is one example of a general flowchart of a process for manufacturing a Wheatstone bridge according to one embodiment of the invention.

### DETAILED DESCRIPTION

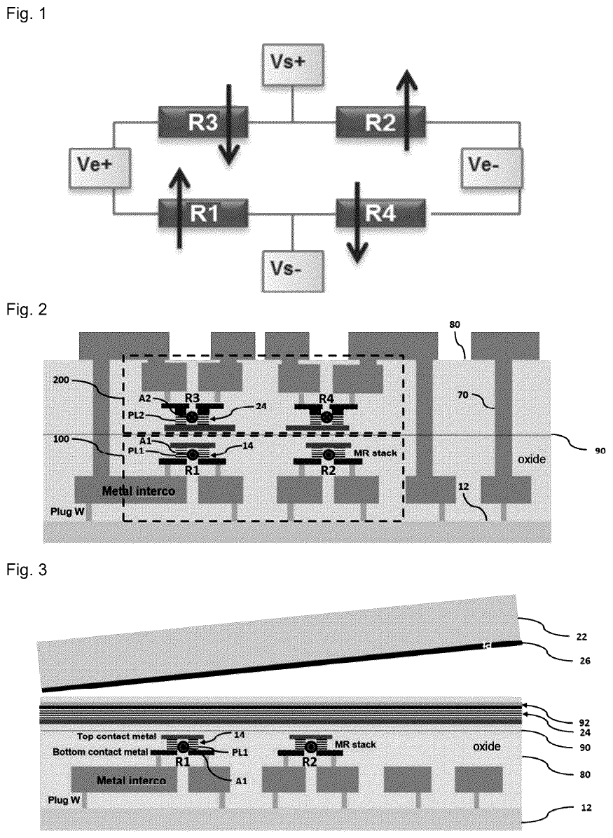

FIG. 1 shows a simplified schematic of a Wheatstone bridge according to one embodiment of the invention. The Wheatstone bridge comprises four magnetic resistors R1, R2, R3, R4 each comprising at least two magnetoresistive devices connected in series. Each magnetic resistor R1, R2, R3, R4 comprises the same number of magnetoresistive devices structured from a stack of layers comprising at least two ferromagnetic layers separated by a non-magnetic layer. Each magnetic resistor may comprise a high number of magnetoresistive devices, for example 10 or more. Advantageously, a high number of magnetoresistive devices makes it possible to obtain a better signal-to-noise ratio and a Wheatstone bridge that is more robust electrically. The Wheatstone Bridge comprises two Wheatstone half-bridges. The first Wheatstone half-bridge comprises the resistors R1 and R3 while the second Wheatstone half-bridge comprises the resistors R2 and R4.

Within a Wheatstone bridge (Wheatstone 1843), potentials Vs⁺, Vs⁻, Ve⁺ and Ve⁻ are measured between each magnetic resistor R1, R2, R3, R4, as shown in FIG. 1. If the resistances of the four magnetic resistors R1, R2, R3, R4 are identical in a magnetic field of zero (H=0), then given a variation in magnetic field the resistances of the magnetic resistors become: R1=R2=R+ΔR and R3=R4=R−ΔR. The voltage Ve=Ve⁺−Ve⁻ measured between the terminals (R2-R3) and terminals (R1-R4) of the Wheatstone bridge may be simplified according to the following formula:
Ve=Vs*ΔR/R, with Vs=Vs⁺−Vs⁻ the voltage applied between the terminal (R1-R3) and the terminal (R2-R4) of the Wheatstone bridge.

The magnetoresistive devices may comprise spin valves or magnetic tunnel junctions. In the TMR case the current flows through the structure, whereas in the GMR case propagation of the current is in the plane of the layers.

The magnetic tunnel junctions used for the purposes of the invention for example have the following structure: buffer layer/synthetic antiferromagnetic layer/reference layer/MgO tunnel barrier/free layer/antiferromagnetic layer/capping layer. The free layer for example comprises CoFeB. The reference layer for example comprises CoFeB magnetically coupled to another layer comprising a synthetic antiferromagnet. It is this magnetic coupling that makes it possible to obtain a reference layer with a coercivity higher than the coercivity of the free layer.

The magnetoresistive devices of each magnetic resistor (R1, R2, R3, R4) are identical. More particularly, the coercivities of the reference layers are identical to one another and the coercivities of the free layers are identical to one another.

The magnetizations of the reference layers of the magnetic resistors of the lower stage (i.e. the stage closest to the substrate), here R1 and R2, are aligned in a first direction. The magnetizations of the reference layers of the magnetic resistors of the upper stage (i.e. the stage furthest from the substrate), here R3 and R4, are aligned in a second direction different from the first direction. Preferably, the second direction is oriented substantially at 180 degrees to the first direction. In FIG. 1, the black arrows represent the magnetization directions of the fixed layers of the magnetic resistors R1, R2, R3, R4.

In this description, the term “substantially” indicates a tolerance of +/−10 degrees. Thus, in the preceding paragraph, that the second direction is oriented substantially at 180 degrees to the first direction means that the angle described between the first direction and the second direction is between 170 and 190 degrees and preferably between 175 and 185 degrees.

In this description, the term “direction” encompasses a direction associated with a sign. Thus, in the preceding paragraph, that the second direction is oriented substantially at 180 degrees to the first direction means that the first direction and the second direction are substantially antiparallel.

Alternatively, the magnetizations of the reference layers of the resistors R1 and R2 are aligned in different directions (oriented substantially at 90 degrees to each other for example) and the magnetizations of the reference layers of the resistors R3 and R4 are aligned in different directions (oriented substantially at 90 degrees to each other for example). Advantageously, this angular configuration makes it possible to determine the orientation of the external magnetic field. This configuration may be obtained through recourse to the shape anisotropy created during structuring of the magnetoresistive devices and to a magnetic anneal with a magnetic field oriented at 45 degrees to the magnetization direction of R1 and R2 and to the magnetization direction of R3 and R4 (FR2954512A1).

Within each magnetoresistive device, when the external magnetic field is zero, the magnetization of the free layer is oriented substantially at 90 degrees to that of the reference layer. Advantageously, this magnetic configuration in which the magnetization of the free layer and the magnetization of the reference layer are perpendicular makes it possible to obtain a substantially linear response from each magnetic resistor at weak magnetic fields. Alternatively, when the external magnetic field is zero, the magnetization of the free layer is substantially parallel to the magnetization of the reference layer or oriented substantially at 180° to the magnetization of the reference layer. In the embodiment considered here, the magnetization of the free layer is located in a plane P orthogonal to the stacking direction of the layers. Alternatively, the magnetization of the free layer is orthogonal to the plane P.

As shown in FIG. 2, the Wheatstone bridge comprises a first stack of layers 14 stacked in a direction z1 and structured into a first Wheatstone device 100, and a second stack of layers 24 stacked in a direction z2 and structured into a second Wheatstone device 200. The first Wheatstone device 100 comprises a first resistor R1 and a second resistor R2, each of said resistors comprising at least two magnetoresistive devices, which comprise a first magnetic layer PL1, the magnetization of which is oriented in a first direction A1, and a second magnetic layer FL1. The first magnetic layer PL1 comprises a magnetic layer or a stack of layers comprising at least two magnetic layers. The second magnetic layer FL1 comprises a magnetic layer or a stack of layers comprising at least two magnetic layers. The second Wheatstone device 200 comprises a third resistor R3 and a fourth resistor R4, each of said resistors comprising at least two magnetoresistive devices, which comprise a third magnetic layer PL2, the magnetization of which is oriented in a second direction A2, and a fourth magnetic layer FL2. The third magnetic layer PL2 comprises a magnetic layer or a stack of layers comprising at least two magnetic layers. The fourth magnetic layer FL2 comprises a magnetic layer or a stack of layers comprising at least two magnetic layers. Within the Wheatstone bridge, the direction A2 is different from the direction A1. The direction A2 is, for example, oriented substantially at 180 degrees to the direction A1. Within the Wheatstone bridge, the upper part of the second Wheatstone device 200 is bonded to the upper part of the first Wheatstone device 100. Electrical interconnect levels 70 allow the first Wheatstone device 100 to be electrically connected to the second Wheatstone device 200. The electrical interconnect levels 70 also make it possible to connect the two Wheatstone devices at the CMOS level. The electrical interconnect levels 70 comprise a set of layers comprising at least one conductive layer such as a metal layer, of aluminum or copper for example. The magnetoresistive devices are insulated from each other by an insulating layer 80, a silicon oxide for example. The upper part of the first Wheatstone device 100 and the upper part of the second Wheatstone device 200 for example comprise the insulating layer 80 and/or are covered with a layer of silicon oxide. The layer of silicon oxide has a thickness greater than or equal to 2 nm and less than or equal to 2 μm.

In the embodiment considered here, the magnetizations of the reference layers PL1 and PL2 are respectively located in planes P1 and P2 that are substantially orthogonal to the stacking directions of the layers z1 and z2, respectively. In the embodiment considered here, the planes P1 and P2 are substantially coincident and may be considered to be a single plane P.

In the embodiment considered here, the resistors R1 and R2 belong to the same plane parallel to the plane P1. In the embodiment considered here, the resistors R3 and R4 belong to the same plane parallel to the plane P2. In the embodiment considered here, the resistors R1 and R3 are aligned along an axis orthogonal to the plane P1 and the resistors R2 and R4 are aligned along another axis orthogonal to the plane P1 as shown in FIGS. 2, 5 and 6.

Alternatively, the magnetizations of the reference layers PL1, PL2 are orthogonal to the plane of the reference layers PL1, PL2. Alternatively, the magnetization of the first magnetic layer PL1 lies in the plane P1 and the magnetization of the third magnetic layer PL2 is orthogonal to the plane P2.

Within the Wheatstone bridge, the upper part of the second Wheatstone device 200 is bonded to the upper part of the first Wheatstone device 100 via a bonding layer 90. The two Wheatstone devices 100, 200 therefore face each other within the Wheatstone bridge. The bonding layer 90 may comprise a metal (titanium for example) an oxide (silicon oxide for example) or a nitride (silicon nitride for example). The bonding layer 90 makes contact with the entire surface of the upper part of the first Wheatstone device 100 and with the entire surface of the upper part of the second Wheatstone device 200. The bonding surface 90 is therefore continuous. Alternatively, the bonding layer 90 is not continuous.

The invention also relates to a magnetic-field sensor comprising at least three Wheatstone bridges according to any of the embodiments described above, wherein three of the at least three Wheatstone bridges are each oriented according to a unit vector, the unit vectors forming a basis of three-dimensional coordinates.

The magnetic-field sensor makes it possible, by virtue of the at least three Wheatstone bridges that it comprises, to determine the strength and orientation, in the three dimensions of space, of the external magnetic field in which the magnetic-field sensor is placed.

The invention also relates to a process for manufacturing a Wheatstone bridge. Various embodiments are possible. These differ mainly in the order in which the various constituent steps of the manufacturing process are carried out. The manufacturing processes described below may advantageously be employed to manufacture a Wheatstone bridge according to one of the embodiments described above.

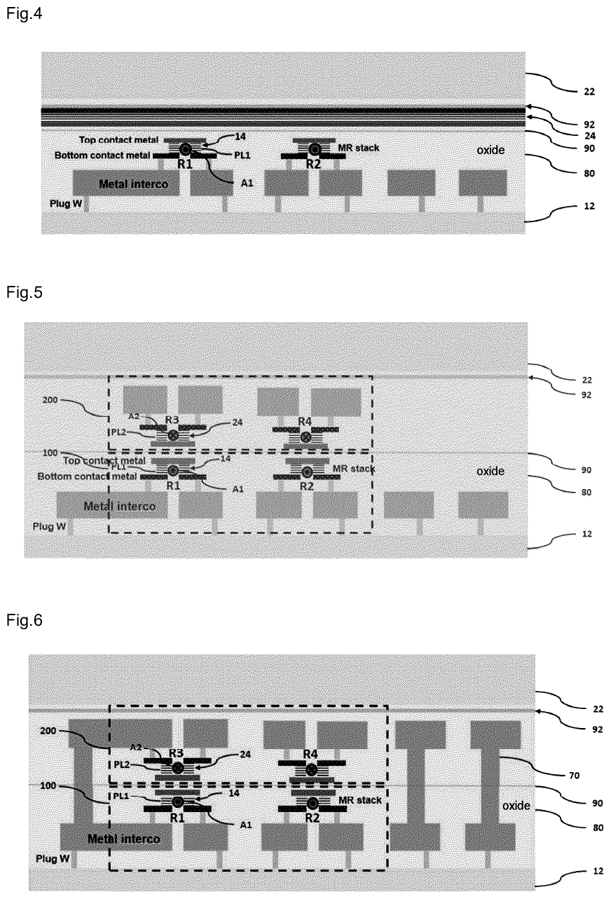

FIGS. 4 to 6 illustrate processes for manufacturing a Wheatstone bridge according to various embodiments of the invention. The various processes for manufacturing a Wheatstone bridge described below comprise:
a step S10 of providing a first wafer 10 comprising:
   a first substrate 12,
   a first stack of layers 14 stacked in a first stacking direction (z1) and placed on the first substrate 12, comprising:
      a first magnetic layer PL1,
      a second magnetic layer FL1,
   the first stack of layers 14 being structured into a first Wheatstone device 100 comprising a first resistor R1 and a second resistor R2, each of said resistors comprising at least two magnetoresistive devices in which the magnetization of the first magnetic layer PL1 is oriented in a first direction A1,
a step S20 of providing a second wafer 20 comprising:
   a second substrate 22,
   a second stack of layers 24 stacked in a second stacking direction z2 and placed on the second substrate 22, comprising:
      a third magnetic layer PL2,
      a fourth magnetic layer FL2,
a first step S30 of structuring the second stack of layers 24 into a second Wheatstone device 200 comprising a third resistor R3 and a fourth resistor R4, each of said resistors comprising at least two magnetoresistive devices in which the magnetization of the third magnetic layer PL2 is oriented in a second direction A2,
a bonding step S40 in which the upper part of the second Wheatstone device (200) is bonded to the upper part of the first Wheatstone device (100),
   wherein the bonding step S40 is carried out in such a way that the first direction A1 is different from the second direction A2.

In the providing step S10, a first wafer 10 is provided. The wafer 10 comprises a first substrate 12 and a first stack of layers 14. The first stack of layers 14 is placed on the first substrate 12 and is stacked in a first stacking direction z1. In the embodiment considered here, the first stacking direction z1 is orthogonal to the plane P1 of the first substrate 12.

The first substrate 12 comprises a silicon substrate. Alternatively, the first substrate 12 comprises sapphire. The first substrate 12 is rigid. Alternatively, the first substrate 12 is flexible. The first substrate 12 is opaque. Alternatively, the first substrate 12 is transparent. Alternatively, the first substrate 12 comprises CMOS electronics.

The first stack of layers 14 comprises layers intended to be structured into spin valves or magnetic tunnel junctions. In the embodiment considered here, the first stack of layers 14 is intended to be structured into magnetic tunnel junctions. The first stack of layers 14 comprises a first magnetic layer PL1 which is a reference magnetic layer, and a second magnetic layer FL1 which is a free magnetic layer. The coercivity of the first magnetic layer PL1 is greater than the coercivity of the second magnetic layer FL1.

Preferably, prior to its structuring into magnetic tunnel junctions, the first stack of layers 14 is subjected to an anneal in a magnetic field oriented in a direction H1. In the embodiment considered here, the direction H1 is oriented in the plane of the first layer PL1. This anneal allows the magnetization of the first layer PL1 to be aligned with the direction H1. The temperature at which the first stack of layers 14 is annealed is, for example, greater than or equal to 250 degrees Celsius and less than or equal to 400 degrees Celsius. Alternatively, the anneal under magnetic field is carried out post-structuring.

During structuring of the first stack of layers 14, the first stack of layers 14 is structured into a first Wheatstone device 100 comprising a first resistor R1 and a second resistor R2, each of said resistors comprising at least two magnetoresistive devices in which the magnetization of the first magnetic layer PL1 is oriented in the first direction A1. The first Wheatstone device 100 is then structured a second time to create electrical connections 71, for example connecting the first resistor R1 to the second resistor R2 and the first resistor R1 and the second resistor R2 at the CMOS level. In the embodiment considered here, the resistors R1 and R2 belong to the same plane parallel to the plane P1.

In the embodiment considered here, in the providing step S10, the first stack of layers 14 is already structured into a first Wheatstone device 100. In the embodiment considered here, the first Wheatstone device 100 already comprises the electrical connections 71.

In the providing step S20, a second wafer 20 is provided. The latter comprises a second substrate 22 and a second stack of layers 24. The second stack of layers 24 is placed on the second substrate 22 and is stacked in a second stacking direction z2. In the embodiment considered here, the second stacking direction z2 is orthogonal to the plane of the second substrate 22. In the embodiment considered here, the first stacking direction z1 and the second stacking direction z2 are chosen so as to be oriented substantially at 180 degrees to each other within the Wheatstone bridge.

The second substrate 22 comprises a silicon substrate. Alternatively, the second substrate 22 comprises sapphire. The second substrate 22 is rigid. Alternatively, the second substrate 22 is flexible. The second substrate 22 is opaque. Alternatively, the second substrate 22 is transparent. Alternatively, the first substrate 12 comprises CMOS electronics.

The second stack of layers 24 comprises layers intended to be structured into spin valves or magnetic tunnel junctions. In the embodiment considered here, the second stack of layers 24 is intended to be structured into magnetic tunnel junctions. The second stack of layers 24 comprises a reference third magnetic layer PL2 and a free fourth magnetic layer FL2.

Preferably, prior to its structuring into magnetic tunnel junctions, the second stack of layers 24 is subjected to an anneal in a magnetic field oriented in a direction H2. In the embodiment considered here, the direction H2 is oriented in the plane of the third layer PL2. This anneal allows the magnetization of the third layer PL2 of the second stack of layers 24 to be aligned with the direction H2. The temperature at which the second stack of layers 24 is annealed is, for example, greater than or equal to 250 degrees Celsius and less than or equal to 400 degrees Celsius. Alternatively, the anneal under magnetic field is carried out post-structuring.

In the embodiment considered here, in the providing step S20, the second stack of layers 24 has already undergone an anneal under magnetic field but has not yet been structured into a second Wheatstone device 200.

In the structuring step S30, the second stack of layers 24 is structured into a second Wheatstone device 200 comprising a third resistor R3 and a fourth resistor R4. The third resistor R3 and the fourth resistor R4 each comprise at least two magnetoresistive devices, in which the magnetization of the third magnetic layer PL2 is oriented in the second direction A2. In the embodiment considered here, the resistors R3 and R4 belong to the same plane parallel to the plane P2.

The structuring step S30 may comprise steps of:
optical lithography,
e-beam lithography,
deposition of materials using techniques such as sputtering, molecular beam epitaxy, chemical vapor deposition, atomic layer deposition,
physical or chemical etching.

In the bonding step S40, the second Wheatstone device 200 is bonded to the first Wheatstone device 100 via a bonding layer 90. The bonding is carried out by bonding the upper part of the second Wheatstone device 200 to the upper part of the first Wheatstone device 100, in such a way that the two Wheatstone devices 100 and 200 end up opposite each other, via the bonding layer 90. Advantageously, the resistors R1 and R3 are close together and aligned along an axis orthogonal to the plane P1 and the resistors R2 and R4 are close together and aligned along another axis orthogonal to the plane P1 as shown in FIGS. 2, 5 and 6. Thus, the Wheatstone devices 100, 200 lie in the same plane and are at the same height, and are thus very close together in the bonding step S90, this increasing the compactness of the device produced.

In the bonding step S40, the second Wheatstone device 200 and the first Wheatstone device 100 are oriented in such a way that the first direction A1 and the second direction A2 are oriented in different directions within the Wheatstone bridge. Preferably, the second Wheatstone device 200 and the first Wheatstone device 100 are oriented in such a way that the first direction A1 and the second direction A2 are oriented substantially at 180 degrees to each other within the Wheatstone bridge. Alternatively, the second Wheatstone device 200 and the first Wheatstone device 100 are oriented in such a way that the first direction A1 and the second direction A2 are oriented substantially at 90 degrees to each other within the Wheatstone bridge, the direction A1 being located in the plane P1 and the direction A2 being orthogonal to the plane P2.

The bonding step S40 is performed by carrying out a chemical treatment of the insulating layer 80 present on the surface of the upper part of the first Wheatstone device 100 and on the surface of the upper part of the second Wheatstone device 200. When the insulating layer 80 is a silicon oxide, for example silica with the chemical formula SiO₂, the chemical treatment creates Si—O—H chemical bonds at the surface of the upper parts of the Wheatstone devices 100, 200. The upper part of the first Wheatstone device 100 and the upper part of the second Wheatstone device 200 are then held in contact with each other during a heat treatment at a temperature greater than or equal to 200 degrees Celsius. The heat treatment makes it possible to convert the Si—O—H chemical bonds present on the surface of the upper parts of the Wheatstone devices 100, 200 into Si—O—Si chemical bonds between the upper parts of the Wheatstone devices 100, 200. Such bonding is called “oxide/oxide bonding” in the remainder of this description. The first Wheatstone device 100 and the second Wheatstone device 200 are thus bonded opposite each other. Advantageously, this process makes it possible to obtain a high-quality bond between the two Wheatstone devices 100, 200, resistant to mechanical and thermal shocks.

Alternatively, the bonding step S40 is performed by carrying out a deposition of metal, oxide, nitride or silicon (for example of titanium, silicon oxide or silicon nitride). The deposition is for example carried out by sputtering, onto the surface of the upper part of the first Wheatstone device 100 and onto the surface of the upper part of the second Wheatstone device 200. The upper parts of the two Wheatstone devices 100, 200 are then held in contact at room temperature or during a heat treatment so as to allow the two surfaces to be bonded. In the remainder of the description, such bonding is called “metal/metal bonding” when metal is deposited and “nitride/nitride bonding” when nitrides are deposited.

The process may also be used to manufacture Wheatstone half-bridges, the first stack of layers 14 being structured into a first Wheatstone quarter-bridge 100 and the second stack of layers 24 being structured into a second Wheatstone quarter-bridge 200.

Preferably, the various embodiments of the processes for manufacturing a Wheatstone bridge described below also comprise a step S50 of removing the second substrate 22 from the second wafer 20.

In the removing step S50, the second substrate 22 is removed from the second wafer 20, for example by etching. The second wafer 10 comprises a stop layer 92 making it possible to stop the etching process and not to etch the second stack of layers 24.

Alternatively, a demounting layer 26, for example comprising a metal, for example platinum, is located between the second substrate 22 and the second stack of layers 24 as illustrated in FIG. 3. In the removing step S50, the second substrate 22 is removed from the second wafer 20 by stressing the demounting layer 26 (FR3082997A1).

Advantageously, removing the second substrate 22 by stressing the demounting layer 26 allows the second substrate 22 to be reused, this having a positive impact in terms of recycling materials and of ecological requirements.

Preferably, the various processes for manufacturing a Wheatstone bridge described below further comprise a second structuring step S60 in which electrical connections 71 within the first Wheatstone device 100 and electrical connections 72 within the second Wheatstone device 200 are made. The electrical connections 71 and 72 made in the structuring step S60 are configured to make it possible, in a subsequent step of the process, in the present case a connecting step S70, to electrically connect the first Wheatstone device 100 and the second Wheatstone device 200 and to electrically connect the two Wheatstone devices 100, 200 at the CMOS level. The electrical connections 71 and 72 may be made by means of the same structuring techniques used in the structuring step S30, namely lithography, etching and deposition techniques. The electrical connections 71 and 72 are made of metal, aluminum for example.

Preferably, the various processes for manufacturing a Wheatstone bridge described below further comprise a connecting step S70 in which the electrical connections 71 and 72 are electrically connected to form the electrical interconnect levels 70 of the Wheatstone bridge, the assembly consisting of the first Wheatstone device 100 and the second Wheatstone device 200 thereby forming a functional Wheatstone bridge.

FIG. 4 illustrates the bonding step S40 of a manufacturing process according to a first embodiment of the invention. In the first embodiment, the first structuring step S30 is carried out after the bonding step S40. In this embodiment, the second structuring step S60 is carried out after the first structuring step S30 and the connecting step S70 is carried out after the second structuring step S60.

FIG. 5 illustrates the bonding step S40 of a manufacturing process according to a second embodiment of the invention. In the second embodiment, the first structuring step S30 is carried out before the bonding step S40. In this embodiment, the second structuring step S60 is carried out after the bonding step S40 and the connecting step S70 is carried out after the second structuring step S60.

Advantageously, the second embodiment makes it possible to employ the same manufacturing process—for example using the same lithography masks—for the first Wheatstone device 100 and the second Wheatstone device 200, this making it possible to manufacture magnetic resistors R1, R2, R3 and R4 with the same properties, for example the same electrical, thermal and mechanical properties.

FIG. 6 illustrates the bonding step S40 of a manufacturing process according to a third embodiment of the invention. In the third embodiment, the second structuring step S60 is carried out on the two Wheatstone devices 100, 200 separately before the bonding step S30 and the connecting step S70. At the end of the second structuring step S60, the electrical connections 71 and 72 of the two Wheatstone devices 100, 200 are flush with the surface of said Wheatstone devices 100, 200. In the third embodiment, in the bonding step S40, hybrid bonding is carried out, i.e. metal/metal bonding is carried out between the electrical connections 71 and 72 to form the interconnect level 70, and oxide/oxide bonding is carried out between the remainder of the surfaces of the upper part of the first Wheatstone device 100 and of the upper part of the second Wheatstone device 200.

Advantageously, the third embodiment is simpler to produce if the Wheatstone bridge to be manufactured is compact. Specifically, the difficulty of carrying out the second structuring step S60 and the connecting step S70 after the bonding step S40 increases as the compactness of the Wheatstone bridge to be manufactured increases.

The three embodiments described above are advantageously implemented at the front end of line. The bonding step S90 is a wafer-to-wafer process. It is thus possible to continue the manufacturing process or to implement new manufacturing steps because, at the front end of line, the manufacturing process is always wafer-scale. Wafer-to-wafer processes differ from flip-chip packaging processes. In the case of an assembly of two Wheatstone half-bridges formed using a flip-chip process, i.e. at the packaging level, it is no longer possible or very difficult to continue technological steps other than those pertaining to packaging.

Alignment of the two Wheatstone devices 100, 200 is also easier and more precise when done in a wafer-to-wafer process than in a flip-chip process.

The wafer-to-wafer process allows direct bonding, often by virtue of hybrid bonding. This makes it possible to obtain Wheatstone devices 100, 200 that are very close to each other and the distance between them is controlled. In the case of the flip-chip process, the chips are assembled via bumps or pillars. This has the consequence of moving the devices further away from each other because these connecting systems are thicker and the distance is less well controlled because there is often melting of material.

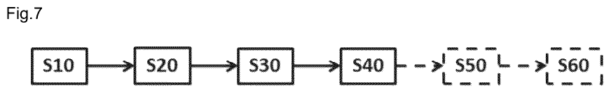

FIG. 7 shows one example of a general flowchart of a process for manufacturing a Wheatstone bridge according to one embodiment of the invention, which contains all the steps of manufacturing a Wheatstone bridge described above. The steps framed in dashed lines are optional steps of the process.

The invention has been described with reference to particular embodiments, but variants are possible. For example:

The magnetic resistors R1, R2, R3 and R4 comprise at least 1000 magnetoresistive devices.

The metal connections 71 and 72 are made of copper.

The step S50 of removing the second substrate is carried out by grinding.

The manufacturing process further comprises a fastening step S80 in which a flux concentrator is added to the first Wheatstone device 100 or to the second Wheatstone device 200, for example by deposition and structuring during the manufacture of the two Wheatstone devices 100, 200. Alternatively, the first wafer 10 provided in the providing step S10 and/or the second wafer 20 provided in the providing step S20 comprise a flux concentrator. The flux concentrator for example comprises a permalloy block. Advantageously, the flux concentrator allows the magnetic field to be concentrated on the Wheatstone bridge and increases its sensitivity to the external magnetic field.

### REFERENCES

(Freitas et al. 2007): P P Freitas, R Ferreira, S Cardoso and F Cardoso, Magnetoresistive sensors, Journal of Physics: Condensed Matter, Volume 19, Number 16, 2007, Pages 165221-21.
(Wu, Yihong 2003): W. Yihong, Nano Spintronics for Data Storage, Encyclopedia of Nanoscience and Nanotechnology, Volume 7, 2003.
(Freitas et al. 2016): P. Freitas, R. Ferreira, S. Cardoso, Spintronic Sensors, Proceedings of the IEEE, Volume 104, Number 10, Pages. 1894-1918, 2016.
(Luong et al. 2015): V.Luong, J. Jeng, B. Lai, J. Hsu, Design of Three-Dimensional Magnetic Field Sensor with Single Bridge of Spin-Valve Giant Magnetoresistance Films, IEEE Transactions on Magnetics, Volume 51, Number 11, Pages 1-1, 2015.
(Wheatstone 1843): C. Wheatstone, The Bakerian lecture. An account of several new instruments and processes for determining the constants of a voltaic circuit. Phil. Trans. R. Soc. Volume 133, Page 303-327, 1843.
(FR2954512A1): O. Redon, Manufacturing of a magnetic structure on one and the same substrate with different magnetization directions, Commissariat à l'Energie Atomique.
(FR3082997A1): G. Le Rhun, C. Dieppedale, S. Fanget, Procédé de transfert de couche(s) de matériau depuis un premier substrat sur un deuxième substrat [Process for transferring layer(s) of material from a first substrate to a second substrate], Commissariat à l'Energie Atomique.

1. A process for manufacturing a Wheatstone bridge, comprising:
a step (S10) of providing a first wafer comprising:
a first substrate,
a first stack of layers stacked in a first stacking direction (z1) and placed on the first substrate, comprising:
a first magnetic layer (PL1),
a second magnetic layer (FL1),
the first stack of layers being structured into a first Wheatstone device comprising a first resistor (R1) and a second resistor (R2), each of said resistors comprising at least two magnetoresistive devices in which the magnetization of the first magnetic layer (PL1) is oriented in a first direction (A1),
a step (S20) of providing a second wafer comprising:
a second substrate,
a second stack of layers stacked in a second stacking direction (z2) and placed on the second substrate, comprising:
a third magnetic layer (PL2),
a fourth magnetic layer (FL2),
a first step (S30) of structuring the second stack of layers into a second Wheatstone device comprising a third resistor (R3) and a fourth resistor (R4), each of said resistors comprising at least two magnetoresistive devices in which the magnetization of the third magnetic layer (PL2) is oriented in a second direction (A2),
a bonding step (S40) wherein the upper part of the second Wheatstone device is bonded to the upper part of the first Wheatstone device via a bonding layer,
wherein the bonding step (S40) is carried out in such a way that the first direction (A1) is different from the second direction (A2).

2. The process as claimed in claim 1, wherein the bonding layer is obtained by chemical treatment of an insulating layer insulating the resistors (R1), (R2), (R3) and (R4).

3. The process as claimed in claim 1, wherein the bonding layer is obtained by depositing a metal, a semiconductor, an oxide or a nitride.

4. The process as claimed in claim 1, further comprising a step (S50) of removing the second substrate from the second wafer.

5. The process as claimed in claim 4, further comprising a second structuring step (S60) wherein the electrical connections of the second Wheatstone device are made.

6. The process as claimed in claim 5, further comprising a connecting step (S70) wherein the first Wheatstone device and the second Wheatstone device are electrically connected.

7. The process as claimed in claim 1, wherein the first structuring step (S30) is carried out after the bonding step (S40).

8. The process as claimed in claim 1, wherein the first structuring step (S30) is carried out before the bonding step (S40).

9. The process as claimed in claim 5, wherein the second structuring step (S60) is carried out before the bonding step (S40) and after the first structuring step (S30).

10. The process as claimed in claim 1, wherein the second wafer further comprises a demounting layer located between the second substrate and the second stack of layers, and wherein the removing step (S50) is carried out by demounting the second substrate by stressing the demounting layer.

11. The process as claimed in claim 10, wherein the demounting layer comprises platinum.

12. The process as claimed in claim 1, wherein the first direction (A1) is oriented substantially at 180 degrees to the second direction (A2).

13. The process as claimed in claim 1, wherein the first direction (A1) and the second direction (A2) are substantially parallel to a plane (P) orthogonal to the first stacking direction (z1) of the first multilayer and to the second stacking direction (z2) of the second multilayer.

14. The process as claimed in claim 1, wherein the first direction (A1) is substantially orthogonal to the second direction (A2).

15. The process as claimed in claim 14, wherein the first direction (A1) is substantially orthogonal to the plane (P) and the second direction (A2) is substantially parallel to a plane (P) orthogonal to the first stacking direction (z1) of the first multilayer and to the second stacking direction (z2) of the second multilayer.

16. The process as claimed in claim 1, wherein the magnetization direction of the first magnetic layer (PL1) is substantially perpendicular to the magnetization direction of the second magnetic layer (FL1), and the magnetization direction of the third magnetic layer (PL2) is substantially perpendicular to the magnetization direction of the fourth magnetic layer (FL2).

17. A Wheatstone bridge comprising:
a first stack of layers structured into a first Wheatstone device comprising a first resistor (R1) and a second resistor (R2), each of said resistors comprising at least two magnetoresistive devices, which comprise:
a first magnetic layer (PL1) the magnetization of which is oriented in a first direction (A1),
a second magnetic layer (FL1),
a second stack of layers structured into a second Wheatstone device comprising a third resistor (R3) and a fourth resistor (R4), each of said resistors comprising at least two magnetoresistive devices, which comprise:
a third magnetic layer (PL2) the magnetization of which is oriented in a second direction (A2),
a second magnetic layer (FL2),
wherein the second direction (A2) is different from the first direction (A1),
wherein the upper part of the first Wheatstone device is bonded to the upper part of the second Wheatstone device via a bonding layer.

18. A magnetic-field sensor comprising at least three Wheatstone bridges as claimed in claim 17, wherein three of the at least three Wheatstone bridges are each oriented according to a unit vector, the unit vectors forming a basis of three-dimensional coordinates.
